(19) United States
(12) Patent Application Publication
(10) Pub. No.: US 2002/0038914 A1
(43) Pub. Date: Apr. 4, 2002

(54) Semiconductor integrated circuit device

(75) Inventors: Keiji Maruyama, Kawasaki-shi (JP); Shigeo Ohshima, Yokohama-shi (JP)

Correspondence Address: HOGAN & HARTSON L.L.P., 500 S. GRAND AVENUE, SUITE 1900, LOS ANGELES, CA, 90071-2611, US

(73) Assignee: KABUSHIKI KAISHA TOSHIBA

(21) Appl. No.: 09/964,032

(22) Filed: Sep. 26, 2001

(30) Foreign Application Priority Data
Sep. 28, 2000 (JP) 2000-297671

(51) Int. Cl. H01L 23/48

(52) U.S. Cl. 257/784

(57) ABSTRACT

A semiconductor integrated circuit device comprises a semiconductor chip, a wiring provided in the semiconductor chip and electrically connected to an external pin and a pin capacitance adjustment circuit configured to variably adjust a capacitance of the wiring.

### CROSS-REFERENCE TO RELATED APPLICATIONS

This application is based upon and claims the benefit of priority from the prior Japanese Patent Application No. 2000-297671, filed Sep. 28, 2000, the entire contents of which are incorporated herein by reference.

### BACKGROUND OF THE INVENTION

1. Field of the Invention

The present invention relates to a semiconductor integrated circuit device, and more particularly, to an adjustment of a parasitic capacitance between pins which is parasitic between external pins.

2. Description of the Related Art

In semiconductor memories, various bit configuration demand is made in accordance with the user's system. For example, in the case of 256 M DDR SDRAM, “64 M×4 bits”, “32 M×8 bits” and “16 M×16 bits” are available.

Individually designing semiconductor memories having various bit configurations is not convenient in terms of the development period, the development resource, the development cost, the productivity or the like.

In order to settle such problems, the current semiconductor memory is provided with a change-over circuit for changing over the bit configuration as shown in FIG. 12. After the manufacturing step of the semiconductor chip is finished, the current semiconductor chip can correspond to a plurality of bit configurations with the same semiconductor chip by operating the change-over circuit.

The semiconductor memory shown in FIG. 12 is set to a “×16 bit” constitution at default. In the case where the “×16 bit” constitution is changed over to the “×4 bit” constitution, the “×4 bit” constitution change-over pad is bonded to the grounding end pin VSS. As a consequence, the output “×4e” of the inverter circuit INV1 is set to the “HIGH” level so that the setting of the structure is changed over to the “×4 bit” constitution through the bit configuration change-over control circuit.

Furthermore, in the case where the structure is changed over to “×8 bit” constitution, the “×8 bit” constitution change-over pad is bonded to the ground pin VSS in the same manner as the case of the “×4 bit” constitution change-over. As a consequence, the outputs “×8e”, of the inverter circuits INV2 are both set to the “HIGH” level, and is not changed over to the “×8 bit” constitution.

Furthermore, in the case where neither the “×4 bit” constitution nor the “×8 bit” constitution is bonded (at default), the node of the pad becomes the “HIGH” level with the normally on PMOS transistor Pch-1, and Pch-2. As a consequence, both the output of the inverter circuit INV1 and the inverter circuit INV2 area both are become the “LOW” level so that the circuits are not changed over to “×4/×8 bit” constitution and is operated as the “×16 bit” constitution semiconductor memory.

### BRIEF SUMMARY OF THE INVENTION

A semiconductor device according to an embodiment of the present invention comprises a semiconductor chip, a wiring provided in the semiconductor chip and electrically connected to an external pin and a pin capacitance adjustment circuit configured to variably adjust a capacitance of the wiring.

### BRIEF DESCRIPTION OF THE SEVERAL VIEWS OF THE DRAWING

FIG. 1 is a circuit diagram showing a semiconductor memory according to a first embodiment of the present invention.

FIG. 2 is a circuit diagram showing a semiconductor memory according to a second embodiment of the present invention.

FIG. 3 is a circuit diagram showing a semiconductor memory according to a third embodiment of the present invention.

FIGS. 4A, 4B, and 4C are views showing examples of the capacitor C11.

FIG. 5 is a plan view showing an example of a first layout of the capacitor C11.

FIG. 6 is a plan view showing an example of a second layout of the capacitor C11.

FIG. 7 is a plan view showing an example of a third layout of the capacitor C11.

FIG. 8 is a plan view showing an example of a fourth layout of the capacitor C11.

FIG. 9 is a circuit diagram showing a pin capacitance adjustment circuit according to a sixth embodiment of the present invention.

FIG. 10 is a circuit diagram showing a pin capacitance adjustment circuit according to a seventh embodiment of the present invention.

FIG. 11A is a perspective view showing a semiconductor package in which an external pin is arranged in two dimensions.

FIG. 11B is a plan view showing a semiconductor package in which the external pin is arranged in two dimensions.

FIG. 12 is a circuit diagram showing a conventional semiconductor memory.

FIG. 13 is a pin arrangement view showing a pin arrangement of a 256 M DDR SDRAM.

FIG. 14 is a sectional view showing a cross section of a typical semiconductor memory package.

FIG. 15 is a view showing a parasitic capacitance between pins.

### DETAILED DESCRIPTION OF THE INVENTION

As one specification is manually provided in which the characteristic of the memory supplied from various semiconductor vendors, there is available a pin capacitance characteristic on the semiconductor memory.

On the pin capacitance characteristic, both the upper limit value and the lower limit value are set respectively as described below. Both the upper limit value and the lower limit value must be set so as to be accommodated to a scope.

Input pin capacitance . . . lower limit value: 2.5 pF, upper limit value: 3.5 pF.

Clock pin capacitance . . . lower limit value: 2.5 pF, upper limit: value 3.5 pF

I/O pin capacitance lower limit value: 4.0 pF, upper limit value: 5.0 pF

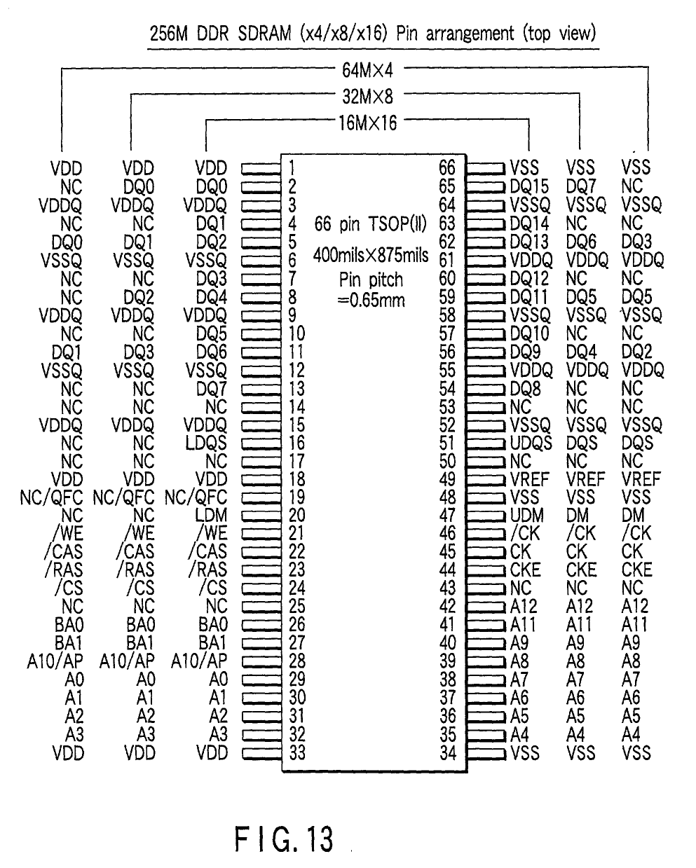

FIG. 13 is a view showing a pin arrangement view of the “×4/×8/×16 bit” constitution of the TSOP (II) package of the 256 M DDR SDRAM of the JEDEC (Joint Electron Devices Engineering Council) standard.

As shown in FIG. 13, the pin number is the same as 66 pins up to the “×4/×8/×16 bit” constitution. Then, in the “×4/×8 bit” constitution, the DQ pin (I/O pin) which becomes surplus as compared, for example, with the “×16 bit” constitution, an NC pin (No connection pin) which is not connected with the semiconductor chip is provided. In many cases, the user uses the NC pin in an electrically floating state.

However, as one component which constitutes a pin capacitance, as shown in FIGS. 14 and 15, there is available a parasitic capacitance between pins which is parasitic between pins. FIG. 15 is a cross section which runs along line A-A of FIG. 14, the section showing a portion of pins No. 3 to No. 6 in the case of the “×4/×8/×16 bit” constitution.

Hereinafter, with respect to the parasitic capacitance between pins, there is considered an example of the parasitic capacitance of the pin No. 5 (DQ0, DQ1) shown in FIGS. 14 and 15.

At the time of the “×4/×8 bit” constitution, with respect to the parasitic capacitance of the pin No. 5, the adjacent pin No. 4 is in an electrically floating state (NC pin), so that the parasitic capacitance C1 between pin No. 5 and pin No. 4. Consequently, at the time of the “×4/×8 bit” constitution, the parasitic capacitance of the pin No. 5 become a sum only the parasitic capacitance C0 between pins between pin No. 5 and No. 6.

However, at the time of the “×16 bit” constitution, the pin No. 4 ceases to be NC pin, the parasitic capacitance of the pin No. 5 becomes a sum (C1+C0) of the parasitic capacitance C1 between pins and a parasitic capacitance C0 between pins.

In this manner, in the conventional semiconductor memory, a specific parasitic capacitance changes at the time of the “×8 bit” constitution and the “×16 bit” constitution.

The circuit in the semiconductor chip is common, and the capacitance in the semiconductor chip is the same at the time of the “×4/×8/×16 bit” constitution. For all that, in the conventional semiconductor memory, the parasitic capacitance between pins changes in accordance with the bit configuration, so that the characteristic between pins changes at the time of the “×4/×8 bit” constitution time and at the time of the “×16 bit” constitution which hinders the case of realizing a plurality of bit configurations with the same semiconductor chip.

In the respective cases of the “×4/×8/×16 bit” constitution, the pin capacitance characteristic cannot be accommodated in the scope of the specification, it is required to add a different capacitance in order to compensate for the parasitic capacitance between pins which decreases in the semiconductor chip in accordance with the bit configuration. As a consequence, a dedicated wiring mask must be prepared which makes it difficult to design a plurality of bit configurations in the same semiconductor chip.

A semiconductor integrated circuit device according to embodiments of the present invention has an adjustment circuit for adjusting the pin capacitance. This adjustment circuit adjusts the capacitance in accordance with the bit configuration in the node of the semiconductor chip connected externally to the outside of the semiconductor chip after the semiconductor chip manufacture step is finished.

Hereinafter, embodiments of the present invention will be explained by referring to the drawings. In this explanation, common portions are denoted by common reference numerals over all the drawings.

(First Embodiment)

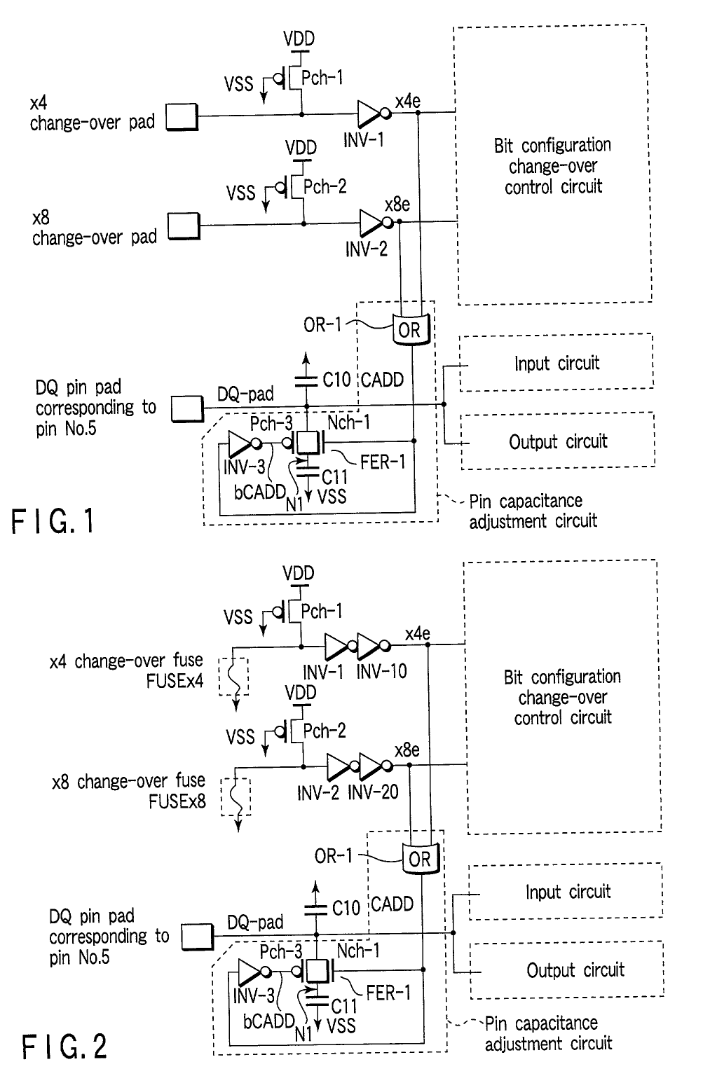

FIG. 1 is a circuit diagram showing s semiconductor memory according to a first embodiment of the present invention. In FIG. 1, pin No. 5 shown, for example, in FIG. 13 is assumed as a pin in which the capacitance is adjusted.

As shown in FIG. 1, the pin capacitance adjustment circuit comprises an OR circuit OR-1 to which an output “×4e, ×8e of×4 bit and×8 bit” change-over circuit is input respectively, and an CMOS type transfer gate circuit FER-1 comprising an NMOS transistor Nch-1 to which an output CADD of the OR circuit OR-1 is input, and a PMOS transistor Pch-3 to which bCADD reversed by the output CADD is reversed by the inverter circuit INV3. One end of this transfer gate circuit FER-1 is connected to the node DQ-pad of the DQ pin pad corresponding to the pin No. 5 when the other end is connected to one of the electrode N1 of the capacitor C11. To the other electrode of the capacitor C11, for example, a ground potential VSS is given.

Next, an operation thereof will be explained.

<At the time of ×4/×8 bit”>

At the time of “×4 bits”, at the stage of the package assemblage step, the “×4 bit” change-over pad is bonded to the ground pin VSS at the step of the package assemblage. As a consequence, the output “×8e” of the inverter circuit INV2 is set to the “HIGH” level, and so that the semiconductor memory according to the first embodiment is set to “×4 bit” via the bit configuration change-over control circuit.

In the same manner, at the time of “×8 bits”, at the stage of package assemblage step, the “×8 bits” change-over pad is bonded to the ground pin VSS. As a consequence, the output “×8e” of the inverter circuit INV2 I is become the “HIGH” level, so that the semiconductor memory according to the first embodiment of the present invention is set to “×8 bits” via the bit configuration change-over control circuit.

In this manner, at the time of “×4/×8 bits”, either of the outputs “×4e” and “×8e” is set to the “HIGH” level. As a consequence, the output CADD of the OR circuit OR-1 is become the “HIGH” level, the transfer gate circuit FER-1 is turned “on” when the node DQ-pad is connected to the capacitor C11 via the transfer gate circuit FER-1. As a consequence, the capacitance of the node DQ-pad becomes a sum (C10+C11) of the capacitance C10 parasitic originally on this node DQ-pad and the capacitor C11.

<At the time of “×16 bits” constitutions>

At the time of “×16 bits”, no bonding is provided on “×4 bit” change-over circuit and “×8 bits” change-over circuit. As a consequence, both the output “×4e” of the inverter circuit INV1 and the output “×8e” of the inverter circuit INV2 are become the “LOW” level with the result that the semiconductor memory according to the first embodiment is set to “×16 bits” through the bit configuration change-over control circuit.

In this manner, at the time of “×16 bits”, the outputs “×4e” and “×8e” are both become the “LOW” level. As a consequence, the output CADD of the OR circuit OR-1 is become the “LOW” level, and the transfer gate circuit FER-1 is turned “off”. As a consequence, the capacitance of the node DQ-pad becomes only the capacitance C10 originally parasitic on the node DQ-pad.

Here, it is desired that the capacitor C11 is set to the same value as the parasitic capacitance C1 between pins which is explained by referring to FIG. 15. As a consequence, the change of the pin capacitance can be conventionally suppressed in accordance with the bit configuration.

For example, the parasitic capacitance C1 between pins is set to about 0.5 pF in the current product. As a consequence, the capacitor C11 is set to the same value as this value, or approximately the same value. At this capacitance value, it is possible to sufficiently form the product in the semiconductor integrated circuit chip.

In this manner, in the semiconductor memory according to the first embodiment, the change in the pin capacitance in accordance with the bit configuration can be suppressed by providing a pin capacitance adjustment circuit.

Furthermore, the pin capacitance adjustment circuit outputs an electric signal CADD for adjusting the pin capacitance with respect to a specific pin with which the pin capacitance is desired to be adjusted in accordance with the potential of the bit configuration change-over signals “×40e” and “×8e”. As a consequence, the pin capacitance can be adjusted without changing the wiring or the like. In order to compensate for the parasitic capacitance between pins which decreases in the semiconductor chip in accordance with the bit configuration, it is not required to prepare a dedicated wiring mask for adding an additional capacitance.

Consequently, the design of a plurality of bit configurations with the same semiconductor chip can be facilitated.

(Second Embodiment)

FIG. 2 is a circuit diagram showing a semiconductor memory according to a second embodiment of the present invention.

As shown in FIG. 2, the point in which the second embodiment is different from the first embodiment is a method for generating bit configuration change-over signals “×4e” and “×8e”.

In the first embodiment, the bit configuration change-over signals “×4e” and “×8e” are respectively generated depending upon whether or not the bit configuration change-over pads are bonded to the grounding pins VSS.

On the other hand, in the second embodiment, the bit configuration change-over signals “×4e” and “×8e” are respectively generated depending upon whether or not the “×4 bit/×8 bit” change-over fuse FUSE “×4” and FUSE “×8” are blown.

Next, the operation will be explained.

<At the time of “×4/×8 bits”>

At the time of “×4 bits”, at the stage at which the semiconductor manufacture step is completed, the “×4” change-over fuse is blown. As a consequence, a high potential VDD (“HIGH” level) is input to the input terminal of the inverter circuit INV1 via the normally on type PMOS transistor Pch-1, so that an output of the inverter circuit INV1 is become the “LOW” level. In the fuse blow method according to the present invention, the logic is reversed with respect to the bonding method shown in the first embodiment. As a consequence, the inverters INV10 and INV20 are respectively added. The inverters INV10 receives an input of the “LOW” level and outputs an output “×4e” of the “HIGH” level. As a consequence, the semiconductor memory according to the second embodiment is set to “×4 bits” through the bit configuration change-over control circuit in the same manner as the semiconductor memory according to the first embodiment.

In a similar manner, at the time of the “×8 bits”, at the stage at which the semiconductor memory manufacture step is completed, the “×8 bit” constitution change-over fuse is blown. As a consequence, a high potential VDD (“HIGH” level) is input to the input terminal of the inverter circuit INV1 via the normally on type PMOS transistor Pch-2, so that an output of the inverter circuit INV1 is become the “LOW” level. The inverters INV20 receives an input of the “LOW” level and outputs an output “×8e” of the “HIGH” level. As a consequence, the semiconductor memory according to the second embodiment is set to “×8 bits” through the bit configuration change-over control circuit.

In this manner, in the semiconductor memory according to the second embodiment, the either of the outputs “×4e” and “×8e” are become the “HIGH” level at the time of “×4/×8 bit”. As a consequence, the output CADD of the OR circuit OR-1 is become the “HIGH” level, and the transfer gate circuit FER-1 is turned on with the result that the node DQ-pad is connected to the capacitor C11 via the transfer gate circuit FER-1. As a consequence, the capacitor C11 of the node DQ-pad becomes a sum (C10+C11) of the capacitance originally parasitic on the node DQ-pad and the capacitor C11.

<At the time of “×16 bit” constitution>

At the time of the “×16 bits”, neither the “×4 bit” change-over fuse FUSE “×4” and the “×8 bit” change-over fuse FUSE “×8” is blown. As a consequence, both the output “×4e” of the inverter circuit INV10 and the output “×8e” of the inverter circuit INV20 are become the “LOW” level. The semiconductor memory according to the second embodiment of the present invention is set to “×16 bits” through the bit configuration change-over control circuit.

In this manner, at the time of the “×16 bits”, both the outputs “×4e” and “×8e” are become the “LOW” level. As a consequence, the output CADD of the OR-1 is become the “LOW” level when the transfer gate circuit FER-1 is turned “off”. As a consequence, the capacitance of the node DQ-pad becomes only the capacitance C10 originally parasitic on this node DQ-pad.

In this manner, in the second embodiment, the same operation as the first embodiment is conducted, so that the same effect as the first embodiment can be obtained. ps (Third Embodiment)

In the first and the second embodiment, the pin capacitance adjustment circuit is controlled by using the bit configuration change-over signals “×4e” and “×8e”. However, it is possible to independently control the pin capacitance circuit. One such example is explained as the third embodiment.

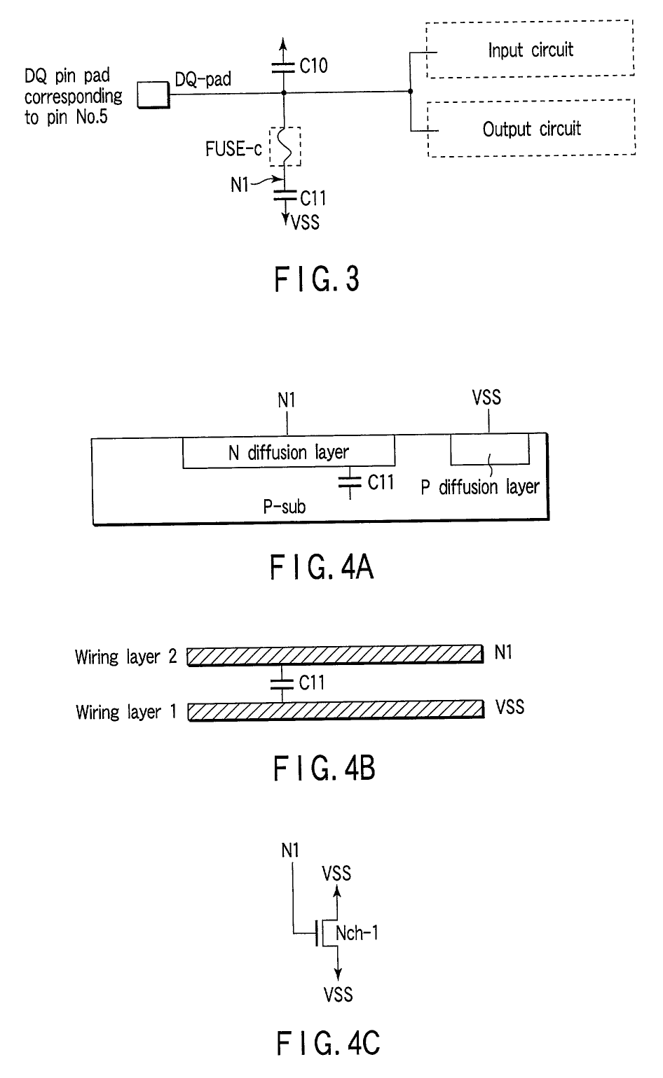

FIG. 3 is a circuit diagram showing a semiconductor memory according to a third embodiment of the present invention.

As shown in FIG. 3, the point in which the third embodiment is different from the first and the second embodiment is that the transfer gate circuit of the pin capacitance circuit is replaced with the fuse element FUSE-c.

The fuse element FUSE-c is blown, for example, at the time of the “×16 bits”. As a consequence, the at the time of the “×16 bits”, in the same manner as the first and the second embodiment, the capacitance is separated from the node DQ-pad when the capacitance of the node DQ-pad becomes only the capacitance C10 originally parasitic on the node DQ-pad.

Furthermore, the fuse element FUSE-c is not blown, for example, at the time of the “×4/×8 bits”. As a consequence, the capacitor C11 is connected to the node DQ-pad in the same manner as the first and the second embodiment. The capacitance of the node DQ-pad becomes a sum of the capacitance C10 and the capacitor C11 originally parasitic on the node DQ-pad.

In such third embodiment, in the same manner as the first embodiment and the second embodiment, the capacitance of a specific pin can be adjusted in accordance with the bit configuration. Consequently, the same effect as the first and the second embodiment can be obtained.

(Fourth Embodiment)

The fourth embodiment is associated with the formation example of the capacitor C11.

FIGS. 4A to 4C are views associated with the example of the capacitor C11.

With respect to the capacitor C11, as shown in FIG. 4A, the capacitor C11 may be formed of the PN junction capacitance. As shown in FIG. 4B, the capacitor C11 may be formed of the capacitance between wirings between the wiring layer 1 and the wiring layer 2.

Furthermore, as shown in FIG. 4C, for example, the capacitor may be formed of the gate capacitance of the NMOS transistor Nch-c.

In this manner, with respect to the capacitor C11, various capacities can be used.

(Fifth Embodiment)

The fifth embodiment is associated with the layout of the capacitor C11.

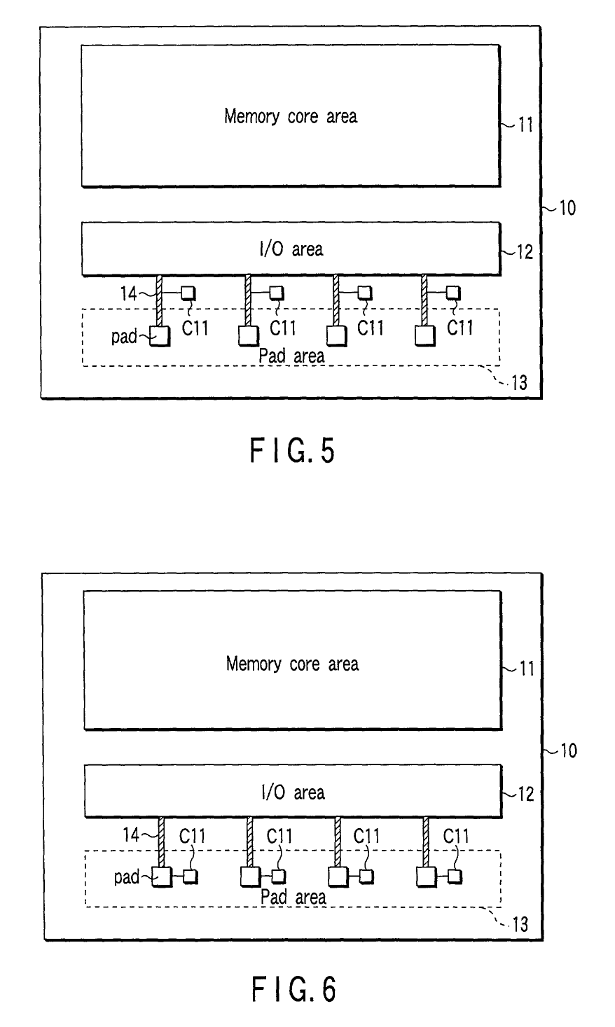

FIG. 5 is a plan view showing a first layout example of the capacitor C11.

As shown in FIG. 5, the semiconductor memory chip 10 basically has three areas; a memory core area 11, an I/O area 12 and a pad area 13.

In the memory core area 11, a memory cell array in which the memory cells are accumulated in a matrix-like configuration, a row/column decoder, a sense amplifier, a command decoder or the like are arranged.

The row/column decoder decodes the row/column address, and selects the address of the above memory cell array.

The sense amplifier amplifies the read data output from the memory cell, or amplifies the write data input from the outside.

The command decoder decodes the command signal to output the inside control signal for controlling the operation of the memory.

Furthermore, in the I/O area 12, the data output circuit, the data input circuit, the address receiver circuit, the command receiver circuit or the like are arranged.

The data output circuit amplifies the read data output from the memory core area 11 to be output to the pad. Furthermore, in the case of the synchronous type semiconductor memory, the read data is amplified and output to the pad in synchronization by a clock signal.

The data input circuit outputs the write data input from the outside to the memory core area 11 by amplifying received via the pad. Furthermore, in the case of the synchronous type semiconductor memory, the row/column address is amplified when the write data is output to the memory core area 11 in synchronization by the clock signal.

The address receiver circuit receives the row/column address input from an external via the pad and amplifies the received row/column address to be output to the memory core area 11. Furthermore, in the case of the synchronization type semiconductor memory, the write data is amplified when being output to the memory core area 11 in synchronization by the clock signal.

The command receiver circuit receives a command signal input from an external via the pad, and amplifies the received command signal to be output to the memory core area 11. The command signal includes, for example, a write enable signal/WE, a column address strobe signal/CAS, a row address strobe signal/RAS, a chip select signal/CS or the like. Furthermore, in the case of the synchronization type semiconductor memory, a command signal is amplified when being output to the memory cell area 11 in synchronization by the clock signal.

The capacitor C11 included in the pin capacitance adjustment circuit 11 can be arranged between the I/O area 12 and the pad area 12 as shown in FIG. 5 in the semiconductor memory having at least three areas 11, 12 and 13.

FIG. 6 is a plan view showing a second layout example of the capacitor C11.

In the first layout example, the capacitor C11 is arranged between the I/O area and the pad area 13. For example, as shown in FIG. 6, it is possible to arrange the capacitor C11 in the pad area 13.

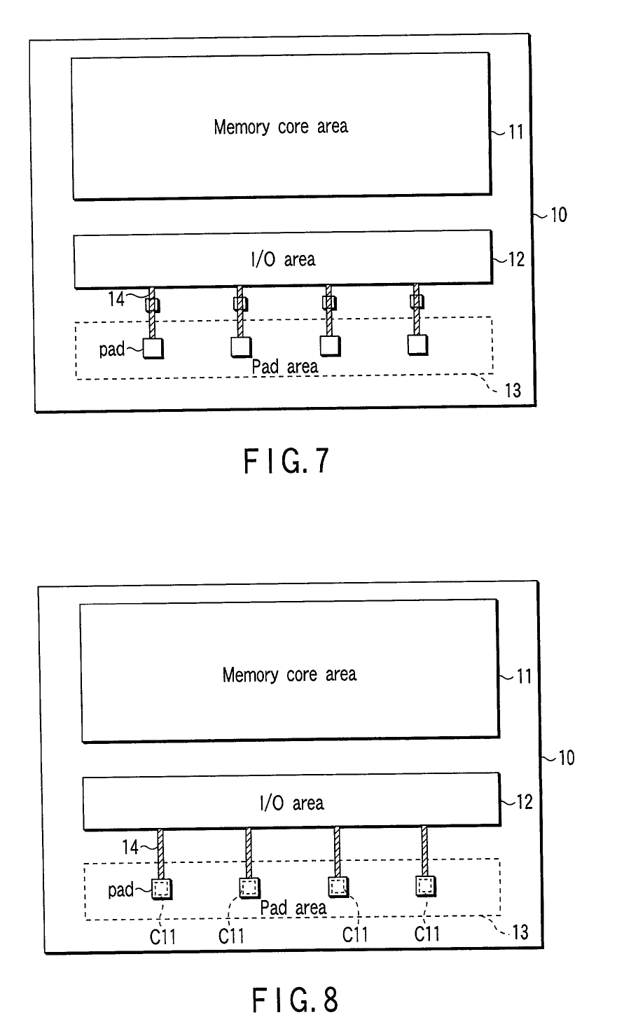

FIG. 7 is a plan view showing a third layout example of the capacitor C11.

In the first layout example, the capacitor C11 is arranged between the wirings 14 connecting the pad and the I/O area 12 (the wiring 14 corresponds to the not DQ-pad shown in FIGS. 1, 2 and 3). For example, as shown in FIG. 7, the capacitor C11 may be arranged under the wiring 14.

FIG. 8 is a plan view showing a layout example of the capacitor C11.

In the second layout example, the capacitor C11 is arranged between pads For example, as shown in FIG. 8, the capacitor C11 may be arranged under the pad (Sixth Embodiment)

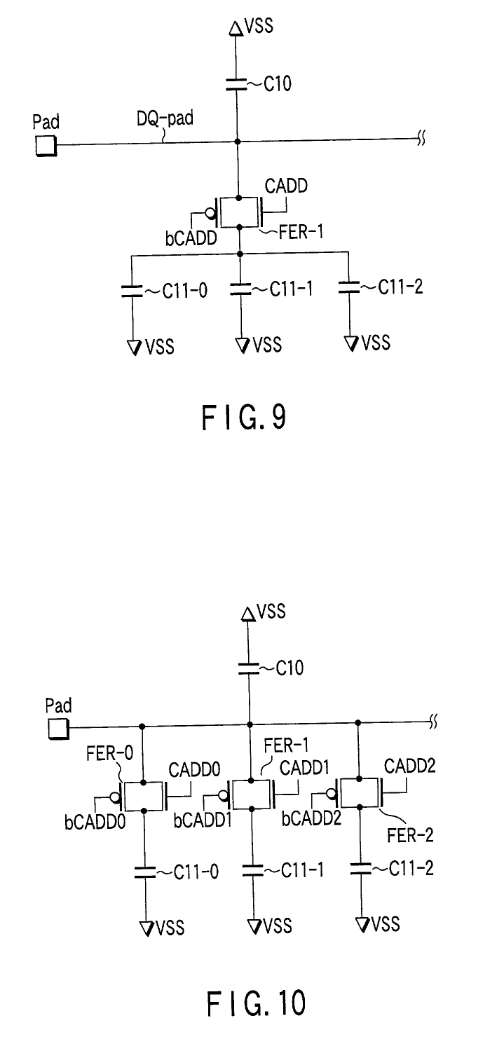

FIG. 9 is a circuit diagram showing a pin capacitance adjustment circuit according to the sixth embodiment of the present invention.

In the sixth embodiment, the capacitor C11 included in the pin capacitance adjustment circuit is become one, but it is possible to provide two capacities C11, three capacities as shown in FIG. 9 (C11-0-C11-2) or four capacities or more.

Such sixth embodiment can be preferably used in the case where it is difficult to obtain the capacitance value approximately same as the parasitic capacitance C1 between pins.

(Seventh Embodiment)

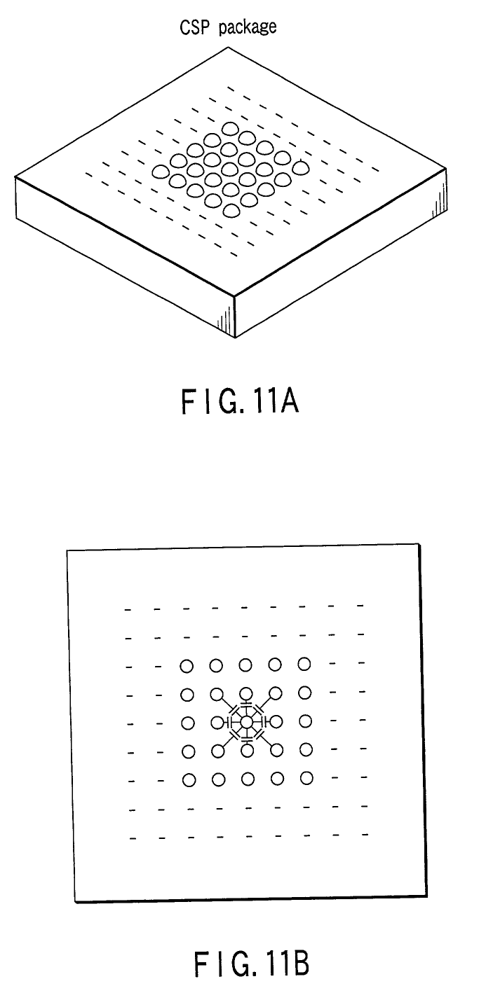

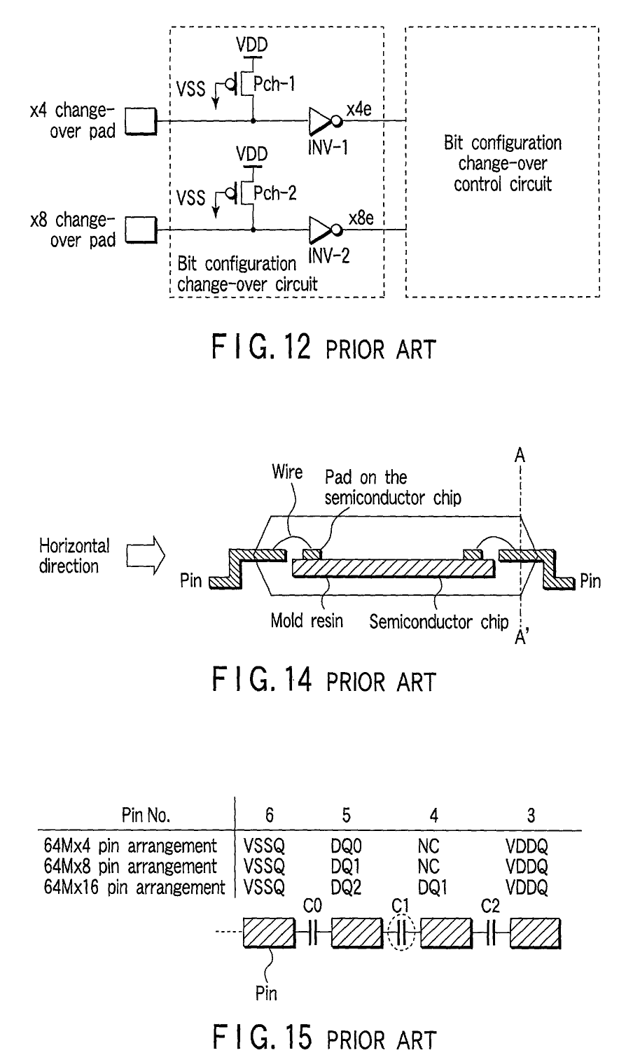

FIG. 10 is a circuit diagram showing a pin capacitance adjustment circuit according to the seventh embodiment of the present invention.

The pin adjustment circuit in the seventh embodiment makes two stages of adjustment as to whether or not the capacitor C11 is added to the capacitance C10. However, it is possible to adjust the stages in two or more stages in a stepwise manner.

The pin capacitance adjustment circuit shown in FIG. 10 is an example in which a four stage adjustment is enabled so that the capacitor C11-0 is added to the capacitance C10, the capacitors C11-0 and C11-1 are added to the capacitance C10, and the capacitors C11-0 and C11-1 are added to the capacitance C10.

The pin capacitance adjustment circuit shown in FIG. 10 can be four states such as all “on”, only one “off”, two “off” and all “off” correspond to the capacitance adjustment signal, for example among the transfer gate circuit FER-0 - FER-2. As a consequence, a four stepwise adjustment is enable.

The pin capacitance adjustment circuit which is capable of making a stepwise adjustment of two stages or more can be favorably used in the semiconductor memory which assumes three states; only one of the two external pins adjacent thereto is set to the floating state in accordance with the bit configuration, for example, in the specific external pin, both pins are set to the floating state, and neither of the both external pins are set to the floating state.

Furthermore, in the TSOP (II) package shown in FIGS. 14 and 15, there are provided only two external pins adjacent thereto. In this case, at least, three or less stages adjustment can only be made.

However, for example, in the CSP package, as shown in FIG. 11A, the external pins are arranged in two dimensions. In the case of such package, as shown in FIG. 11B, in a specific external pin, for example, eight external pins adjacent thereto are provided. In such a case, at least nine or less stages adjustment is required.

Consequently, the pin capacitance adjustment circuit which enables two or more stepwise adjustment can be effectively applied, more particularly, in the case where the CSP packages as shown in FIGS. 11A and 11B are used.

As has been described above, the present invention has been explained from the first to the seventh embodiments. The present invention is not limited to these embodiments. In the practice thereof, the embodiments can be modified in various ways within the scope of not departing from the gist of the invention.

For example, in the above embodiments, the external pins in which the capacitance is adjusted is used as a data pin, but this may be an address pin, a command pin, and a clock pin.

Furthermore, it goes without saying that in each of the above embodiments can be put into practice in a single manner or in an appropriate combination thereof.

Furthermore, each of the above embodiments includes various stages of the invention, and various stages of the invention can be extracted with an appropriate combination of the plurality of constituent elements disclosed in each of the embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device comprising:
a semiconductor chip;
a wiring provided in the semiconductor chip and electrically connected to an external pin; and
a pin capacitance adjustment circuit configured to variably adjust a capacitance of the wiring.

2. The device according to claim 1, wherein the pin capacitance adjustment circuit variably adjusts the capacitance of the wiring in accordance with a bit configuration change-over signal.

3. The device according to claim 2, wherein the pin capacitance adjustment circuit includes the capacitor and a transfer gate circuit provided between the capacitor and the wiring; and
the transfer gate circuit connects the capacitor to the wiring in accordance with the bit configuration change-over signal.

4. The device according to claim 1, wherein the pin capacitance adjustment circuit includes a capacitor and a fuse element provided between the capacitor and the wiring.

5. The device according to claim 2, wherein the capacitance value of the capacitor becomes approximately equal to the parasitic capacitance value between the external pin and another external pin.

6. The device according to claim 3, wherein the capacitance value of the capacitor becomes approximately equal to the parasitic capacitance value between the external pin and another external pin.

7. The device according to claim 4, wherein the capacitance value of the capacitor becomes approximately equal to the parasitic capacitance value between the external pin and another external pin.

8. The device according to claim 2, wherein the capacitor is arranged in a pad area provided on the semiconductor chip, the area having a pad arranged therein.

9. The device according to claim 3, wherein the capacitor is arranged in a pad area provided on the semiconductor chip, the area having the pad arranged therein.

10. The device according to claim 4, wherein the capacitor is arranged in a pad area provided on the semiconductor chip, the area having the pad arranged therein.

11. The device according to claim 2, wherein the capacitor is arranged in an I/O area provided in the semiconductor chip, the area having a circuit arranged therein and connected to a pad.

12. The device according to claim 3, wherein the capacitor is arranged in an I/O area provided in the semiconductor chip, the area having a circuit arranged therein and connected to a pad.

13. The device according to claim 4, wherein the capacitor is arranged in an I/O area provided in the semiconductor chip, the area having a circuit arranged therein and connected to a pad.

14. The device according to claim 1, wherein the pin capacitance adjustment circuit adjusts stepwise the capacitance of the wiring.

15. The device according to claim 2, wherein the pin capacitance adjustment circuit adjusts stepwise the capacitance of the wiring.

16. The device according to claim 3, wherein the pin capacitance adjustment circuit adjusts stepwise the capacitance of the wiring.

17. The device according to claim 4, wherein the pin capacitance adjustment circuit adjusts stepwise the capacitance of the wiring.
